(19) United States
(12) Patent Application Publication
(10) Pub. No.: US 2025/0275362 A1
(43) Pub. Date: Aug. 28, 2025

(54) DISPLAY APPARATUS

(71) Applicant: LG Display Co., Ltd., Seoul (KR)

(72) Inventors: Eon-Ho CHA, Paju-si (KR); Hun-Bae IM, Paju-si (KR); Yoon-Seok LEE, Paju-si (KR); Gyu-Hyeong HAN, Paju-si (KR); Sang-Bin SHIN, Paju-si (KR); Dae-Hee HAN, Paju-si (KR)

(73) Assignee: LG Display Co., Ltd., Seoul (KR)

(21) Appl. No.: 18/953,797

(22) Filed: Nov. 20, 2024

(30) Foreign Application Priority Data
Feb. 27, 2024 (KR) 10-2024-0027727

(51) Int. Cl. H10K 59/121; H10K 59/122; H10K 59/127; H10K 59/131; H10K 59/18

(52) U.S. Cl. CPC H10K 59/1213; H10K 59/122; H10K 59/127; H10K 59/131; H10K 59/18

(57) ABSTRACT

A display panel can include a first substrate and a second substrate having a display region and a non-display region adjacent to the display region, a thin film transistor and a light emitting element arranged in each of a plurality of subpixels included in the display region, a dam arranged at the non-display region and an end of the display region between the first substrate and the second substrate, and a protective layer disposed on a side surface of the non-display region and a side surface of the end of the display region.

### CROSS-REFERENCE TO RELATED APPLICATIONS

The present application claims priority to Korean Patent Application No. 10-2024-0027727, filed in the Republic of Korea on Feb. 27, 2024, the entire contents of which is hereby expressly incorporated by reference into the present application.

### BACKGROUND

### Field

The present disclosure relates to a display apparatus that can have various sizes and shapes.

### Discussion of the Related Art

Recently, with development of multimedia, a need for display apparatuses is increasing. In response to this need, flat panel display apparatuses such as liquid crystal display apparatuses, plasma display apparatuses, and organic electroluminescent display apparatuses are being commercialized. Among these display apparatuses, organic electroluminescent display apparatuses are widely used because they have high response speed, high brightness, and good viewing angle.

Meanwhile, as the range of applications of the display apparatuses increases, a demand for large-area display apparatuses and display apparatuses of various shapes that can be applied to various electronic devices is increasing, but realistically there can be limitations in manufacturing such display apparatuses.

### SUMMARY OF THE DISCLOSURE

An advantage of the present disclosure is to provide a display panel that can be manufactured in various sizes by simplified manufacturing processes.

Another advantage of the present disclosure is to provide a tiling display apparatus including display panels of various sizes.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display panel includes a first substrate and a second substrate which include a display region including a plurality of subpixels and a non-display region outside the display region; a thin film transistor and a light emitting element arranged in each of the plurality of subpixels; a dam arranged at the non-display region and an end of the display region between the first substrate and the second substrate; and a protective layer formed on a side surface of the non-display region and a side surface of the end of the display region.

In another aspect, a display apparatus includes a support substrate, and a plurality of display panels, where one of which is the above display panel, and where the plurality of display panels are mounted on the supporting substrate.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain the principles of the disclosure. In the drawings:

FIG. 1 is a view illustrating a display apparatus according to some embodiments of the present disclosure;

FIG. 2 is a schematic block diagram of a subpixel of a display apparatus according to some embodiments of the present disclosure;

FIG. 3 is a circuit diagram illustrating a subpixel of a display apparatus according to some embodiments of the present disclosure;

FIG. 4 is a view schematically illustrating a display panel according to some embodiments of the present disclosure;

FIGS. 5A and FIG. 5B are views specifically illustrating a structure of a display panel according to some embodiments of the present disclosure; and

FIGS. 6A to 6G are views illustrating a method of manufacturing a display apparatus according to an embodiment of the present disclosure.

### DETAILED DESCRIPTION OF THE EMBODIMENTS

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure can be defined by the scope of the claims. Here, the term “can” fully encompasses all the meanings and coverages of the term “may.”

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description. Furthermore, in describing the present disclosure, if it is determined that a detailed description of the related known technology unnecessarily obscure the subject matter of the present disclosure, the detailed description thereof can be omitted. When ‘comprising’, ‘including’, ‘having’, ‘consisting’, and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

Respective features of various embodiments of the present disclosure can be partially or wholly connected to or combined with each other and can be technically interlocked and driven variously, and respective embodiments can be independently implemented from each other or can be implemented together with a related relationship.

In describing components of the present disclosure, terms such as first, second, A, B, (a), (b) and the like can be used. These terms are only for distinguishing the components from other components, and an essence, order, order, or number of the components is not limited by the terms. Further, when it is described that a component is “connected”, “coupled” or “contact” to another component, the component can be directly connected or contact the another component, but it should be understood that other component can be “interposed” between the components, or the components can be “connected”, “coupled” or “contact” through other component.

In this disclosure, a “display apparatus” can include a narrowly defined display apparatus, such as a display module or the like, including a display panel and a driving portion for driving the display panel. Furthermore, the “display apparatus” can include a complete product or final product which is a notebook computer, a television, a computer monitor, an automotive device or equipment display including other type of vehicle, or a set electronic device or set device or set apparatus such as a mobile electronic device which is a smart phone, an electronic pad or the like, including the display module or the like.

Therefore, the display apparatus of this disclosure can include a narrowly defined display apparatus itself such as the display module or the like, and/or an application product or a set device that is an end-user device, including the display module or the like.

Hereinafter, embodiments of the present disclosure are described in detail with reference to the drawings. All the components of each display apparatus/device according to all embodiments of the present disclosure are operatively coupled and configured.

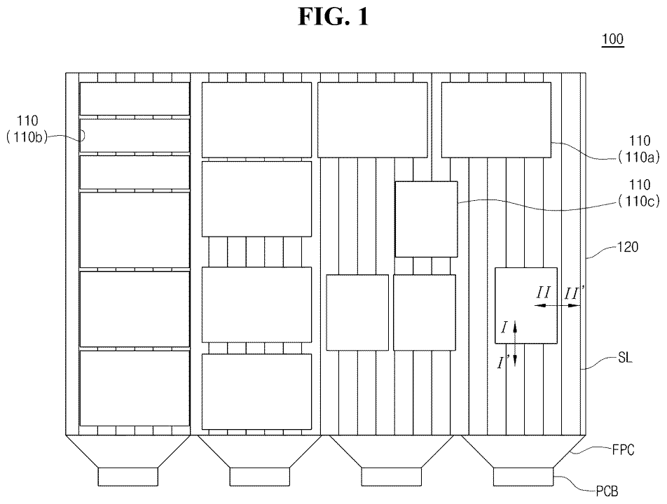

FIG. 1 is a view illustrating a display apparatus according to some embodiments of the present disclosure.

As shown in FIG. 1, a display apparatus 100 of the present disclosure is a tiling display apparatus in which a plurality of display panels 110 are tiled. The tiling display apparatus 100 is configured such that a plurality of display panels 110 are arranged on a large-area support substrate 120 and are electrically connected by signal lines SL to operate as a single display apparatus.

The display panels 110 arranged on the support substrate 120 can have various sizes. For example, a plurality of first display panels 110a can have a first area, and a second display panel 110b and a third display panel 110c can have a second area smaller than the first area. In this case, the first to third display panels 110a to 110c can be display panels having the same structure formed through the same processes. For example, the first to third display panels 110a to 110c can be configured by forming thin film transistors, various lines and light emitting elements on a substrate of the same area through the same process.

The second display panel 110b can be formed by forming the same area as the first display panel 110a and then cutting and removing some region along a direction, for example, a horizontal direction. In addition, the third display panel 110c can be formed by forming the same area as the first display panel 110a and then cutting and removing some region along a direction, for example, a vertical direction.

One ends of a plurality of flexible circuit boards FPC are attached to the support substrate 120, and printed circuit boards PCB are attached to the other ends of the plurality of flexible circuit boards FPC. The flexible circuit boards FPC are flexible base films that can supply power voltages and data voltages to the first to third display panels 110a to 110c. A number of the flexible circuit boards FPC can be changed variously depending on design, but not limited thereto.

The printed circuit board PCB can be placed on the other end of the corresponding flexible circuit board FPC and electrically connected to the flexible circuit board FPC.

ICs that generate various signals and supply them to the first to third display panels 110a to 110c can be mounted on the printed circuit boards PCB. For example, an image processing portion, a timing control portion, a power supply portion, etc. can be placed on the printed circuit board PCB.

The image processing portion outputs image data supplied from an outside and driving signals for driving various components. For example, the driving signals output from the image processing portion can include a data enable signal, a vertical synchronization signal, a horizontal synchronization signal, and a clock signal.

The timing control portion receives the image data and the driving signals from the image processing portion. The timing control portion generates and outputs a gate control signal (or gate timing control signal) for controlling operation timing of a gate driving portion and a data control signal (or data timing control signal) for controlling operation timing of a data driving portion based on the driving signals from the image processing portion.

The power supply portion outputs a high-potential voltage and a low-potential voltage and supplies them to the first to third display panels 110a to 110c.

The driving signals such as the data enable signal, the vertical synchronization signal, the horizontal synchronization signal, and the clock signal, the control signals such as the gate control signal and the data control signal, and the power voltages are supplied to the first to third display panels 110a to 110c from the printed circuit boards PCB through the flexible circuit boards FPC and the signal lines SL.

The first to third display panels 110a to 110c each include a plurality of subpixels and display images. The subpixels SP can include a red subpixel, a green subpixel, and a blue subpixel, or can include a white subpixel, a red subpixel, a green subpixel, and a blue subpixel. At this time, the white, red, green, and blue subpixels SP can all be formed with the same area, but can be formed with different areas.

Hereinafter, the first to third display panels 110a to 110c are mainly described as organic light emitting display panels, but are not limited thereto, and can be liquid crystal display panels, micro light emitting diode (LED) display panels, or mini LED display panels.

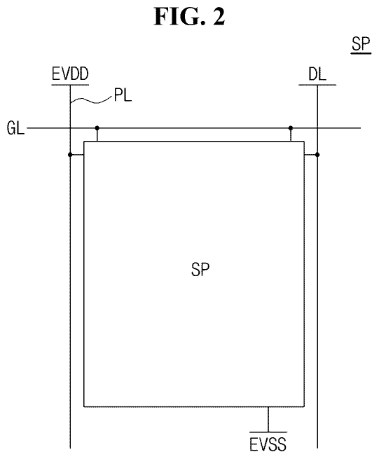

FIG. 2 is a schematic block diagram of a subpixel of first to third display panels of a display apparatus according to some embodiments of the present disclosure.

As shown in FIG. 2, one or each subpixel SP can be connected to a gate line GL, a data line DL, a first power line PL supplying a high-potential voltage EVDD, and a second power line supplying a low-potential voltage EVSS. The subpixel SP can include a plurality of thin film transistors and a storage capacitor depending on a configuration of a pixel circuit. For example, the subpixel SP can be configured with a 2TIC structure in which two transistors and one capacitor is formed in the subpixel SP, but not limited thereto. The subpixel SP can be configured with 3TIC, 4TIC, 5TIC, 6TIC, 7TIC, 3T2C, 4T2C, 5T2C, 6T2C, 7T2, 8T2C, etc.

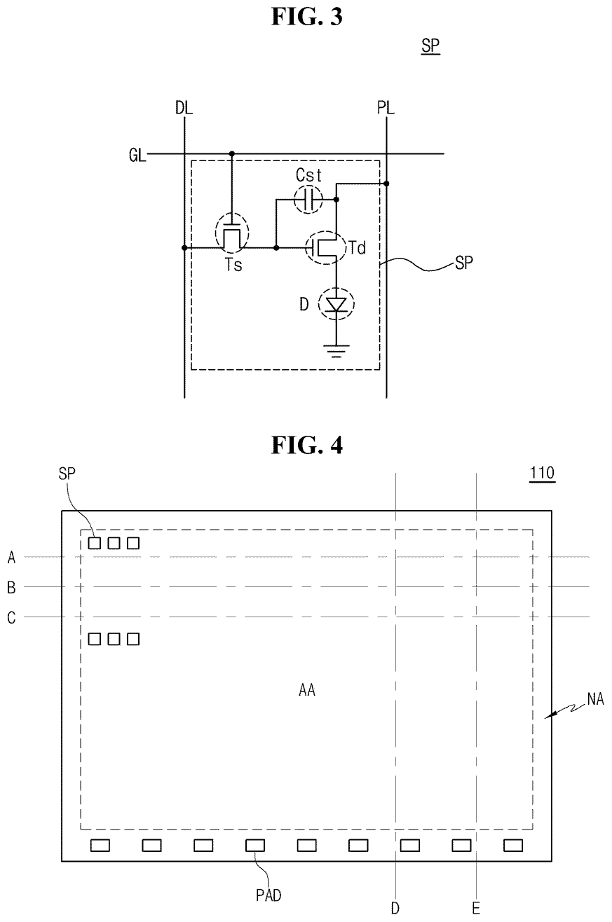

FIG. 3 is a circuit diagram illustrating a subpixel of first to third display panels of a display apparatus according to some embodiments of the present disclosure.

As shown in FIG. 3, the first to third display panels 110a to 110c of the display apparatus according to some embodiments of the present disclosure each include the gate line GL, the data line DL, and the power line PL that cross with each other to define the subpixel SP.

A switching transistor Ts, a driving transistor Td, a storage capacitor Cst, and an organic light emitting element (or organic light emitting diode) D are disposed in the subpixel SP. The switching transistor Ts is connected to the gate line GL and the data line DL, the driving transistor Td and the storage capacitor Cst are connected between the switching transistor Ts and the power line PL, and the organic light emitting element D is connected to the driving transistor Td.

In the above configuration, when the switching transistor Ts is turned on according to a scan signal (or gate signal) applied to the gate line GL, a data signal applied to the data line DL is supplied to a gate electrode of the driving transistor Td and one electrode of the storage capacitor Cst through the switching transistor Ts.

The driving transistor Td is turned on according to the data signal applied to the gate electrode thereof, and as a result, a current proportional to the data signal flows from the power line PL through the driving transistor Td to the organic light emitting element D, and the organic light emitting element D emits light with a brightness proportional to the current flowing through the driving transistor Td.

At this time, the storage capacitor Cst is charged with a voltage proportional to the data signal, so that the voltage of the gate electrode of the driving transistor Td is maintained constant during one frame.

In this example, only two transistors Td and Ts and one capacitor Cst are provided in the subpixel SP, but this not limited thereto, and three or more transistors and two or more capacitors can be provided.

FIG. 4 is a view schematically illustrating a display panel according to some embodiments of the present disclosure, and shows forming various shapes of display panels 110 through a cutting process.

As shown in FIG. 4, the display panel 110 according to some embodiments of the present disclosure includes a display region AA (or active area) where an actual image is displayed and a non-display region NA (or non-active area). The non-display region NA can surround the display region AA entirely or only in part(s).

A plurality of subpixels SP are arranged in the display region AA. The subpixels SP can include a red subpixel, a green sub-pixel, and a blue subpixel. In addition, the subpixels SP can further include a white subpixel.

A plurality of gate lines and data lines are arranged in the display region AA, and the subpixels SP are arranged at the crossing portions of the gate lines and the data lines. In each subpixel SP, a thin film transistor which is a switching element, and a display element for implementing an actual image are arranged.

The display element can include one of various display elements. For example, the display element can be an organic light emitting display element, a liquid crystal display element, a quantum dot display element, a micro LED display element, or a mini LED display element.

A gate driving portion and a data driving portion that apply various signals to the subpixel SP can be arranged in a non-display region NA. The gate driving portion applies a scan signal to the subpixel SP through the gate line, and the data driving portion applies an image signal to the subpixel SP through the data line. In addition, a plurality of pads PAD are arranged in the non-display region NA of a lower part of the display panel AA.

The display apparatus 100 according to some embodiments of the present disclosure shown in FIG. 1 is a display apparatus in which the plurality of display panels 110a, 110b and 110c are tiled. At this time, the first to third display panels 110a to 110c of different sizes can be formed by cutting the display panel 110 shown in FIG. 4. For example, in the present disclosure, after forming the display panel 110 of a specific size, by selectively cutting the display panel 110 along a plurality of cutting lines A, B, C, D and E, any one of the display panels 110a, 110b and 110c of various sizes can be manufactured.

The display panel 110 can be tiled and used on the display apparatus 100 as it is manufactured. In addition, the display panel 110 can be cut along any one of horizontal cutting lines A, B and C and tiled on the display apparatus 100, or can be cut along any one of vertical cutting lines D and E and tiled on the display apparatus 100.

For example, the first display panel 110a of the display apparatus 100 shown in FIG. 1 can use the display panel 110 of FIG. 4 without cutting the display panel 110. In addition, the second display panel 110b of the display apparatus 100 shown in FIG. 1 can use the display panel 110 cut along the horizontal cutting line A, B or C, and the third display panel 110c can use the display panel 110 cut along the vertical cutting line D or E.

The pads PAD of the display panel 110 tiled on the support substrate 120 electrically contacts the signal lines SL formed on the support substrate 120, so that the driving signals such as the data enable signal, the vertical synchronization signal, the horizontal synchronization signal, and the clock signal, the control signals such as the gate control signal and the data control signal, and the power voltages are applied to the display panel 110.

In addition, the display panel 110 cut along the cutting line A, B, C, D or E may not be tiled and used for a display apparatus, and a single cut display panel 110 itself can be used as a display apparatus. In this case, since the display panels 110 of various sizes can be formed through the same manufacturing process line, it is possible to manufacture the display panels 110 of various sizes at low manufacturing cost. In addition, since the display panels 110 with defects can be recycled, product yield can be significantly improved. In a case where defect is located in a certain region of the display panel 110, for example, between the cutting lines B and C, the display panel 110 can be recycled by cutting it along the cutting line C, D or E.

As such, in the display panel 110 of the present disclosure, a region to be cut and removed is also a region where an image is displayed, so that the same subpixels SP and circuits are formed over the entire display region AA of the display panel 110 including the cutting lines A, B, C, D and E.

Meanwhile, in the display apparatus 100 according to some embodiments of the present disclosure, since the display panel 110 is cut, a part of the subpixels SP is directly exposed to an outside, and thus a defect occurs due to moisture penetration. In the present disclosure, in order to prevent moisture from penetrating through the exposed side surface, before cutting the display panel 110, an organic layer and a cathode of the display region AA inside the cutting line A, B, C, D or E are selectively removed through laser ablation, and then the removed region is filled with a dam containing a getter component. This is described in detail below.

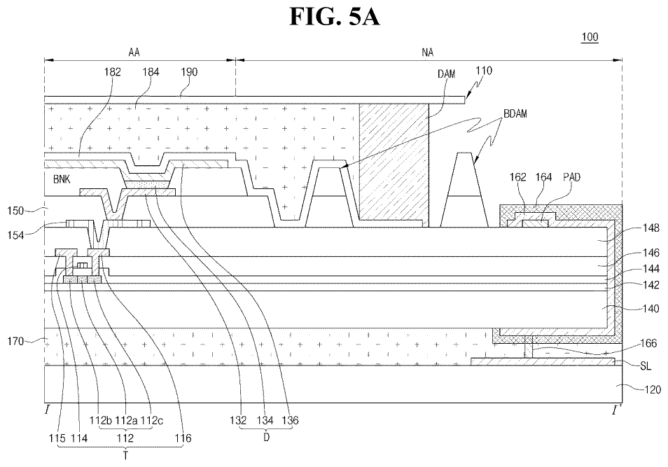

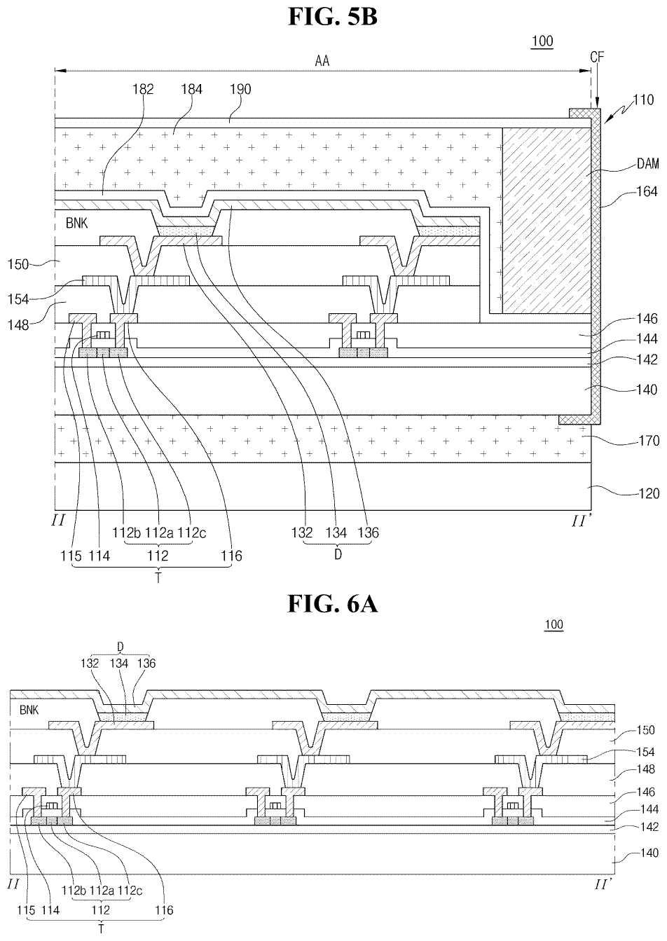

FIG. 5A and FIG. 5B are views specifically illustrating a structure of a display panel according to some embodiments of the present disclosure.

Particularly, FIG. 5A is a cross-sectional view taken along a line I-I′ of FIG. 1, and FIG. 5B is a cross-sectional view taken along a line II-II′ of FIG. 1. At this time, for convenience of explanation, some subpixels SP of the display region AA of the third display panel 110c and the non-display region NA are shown. FIG. 5A includes the display region AA and the non-display region NA on a lower side of the display region AA where the pad PAD is formed, and FIG. 5B includes the display region AA cut along the vertical cutting line D or E so that a right side has a cut surface.

As shown in FIGS. 5A and FIG. 5B, a buffer layer 142 is formed on a first substrate 140. The first substrate 140 can be formed of a rigid material such as glass, or can be formed of a plastic material such as polyimide, polymethylmethacrylate, polyethylene terephthalate, polyethersulfone, or polycarbonate, but not limited thereto.

For example, when the first substrate 140 is formed of polyimide, it can be configured with a plurality of polyimide layers, and an inorganic layer can be further disposed between the polyimide layers, but not limited thereto.

The buffer layer 142 is formed over the entire first substrate 140. The buffer layer 142 can serve to improve adhesive strength between layers formed thereon and the first substrate 140, and serve to block various types of defects such as alkaline components leaking from the first substrate 140. In addition, the buffer layer 142 can delay diffusion of moisture or oxygen that has penetrated the first substrate 140.

The buffer layer 142 can be formed of a single layer of SiNx or SiOx, or multiple layers using at least one of SiNx or SiOx. When the buffer layer 142 is formed of the multiple layers, SiOx and SiNx can be formed alternately. The buffer layer 142 can be omitted based on type and material of the first substrate 140, structure and type of a thin film transistor T, etc.

The thin film transistor T is formed on the buffer layer 142 of the display region AA. For convenience of explanation, only a driving thin film transistor among various thin film transistors that can be arranged is illustrated, but other thin film transistor such as a switching thin film transistor can also be included. In addition, although the thin film transistor T is illustrated as having a top gate structure in the drawing, it is not limited to this structure and can be implemented with other structure such as a bottom gate structure.

The thin film transistor T includes a semiconductor layer 112 disposed on the buffer layer 142, a gate insulating layer 144 formed on the semiconductor layer 112, a gate electrode 114 disposed on the gate insulating layer 144, an interlayered insulating layer 146 formed on the gate electrode 114, and a source electrode 115 and a drain electrode 116 disposed on the interlayered insulating layer 146.

The semiconductor layer 112 can be formed of a polycrystalline semiconductor. For example, the polycrystalline semiconductor can be formed of low temperature poly silicon (LTPS) with high mobility, but not limited thereto.

In addition, the semiconductor layer 112 can be formed of an oxide semiconductor. For example, it can be formed of one of IGZO (Indium-gallium-zinc-oxide), IZO (Indium-zinc-oxide), IGTO (Indium-gallium-tin-oxide), and IGO (Indium-gallium-oxide), but not limited thereto. The semiconductor layer 112 includes a channel region 112a in a central region and a source region 112b and a drain region 112c as doping regions on both sides.

The gate insulating layer 144 can be formed over the entire first substrate 140, or can be formed only in some regions, for example, under the gate electrode 113. The gate insulating layer 144 can be formed as a single layer or multiple layers using an inorganic material such as SiOx and/or SiNx, but not limited thereto.

The gate electrode 114 is formed of metal. For example, the gate electrode 113 can be formed as a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto.

The interlayered insulating layer 146 can be formed over the entire substrate 140, or can be formed only in some regions. The interlayered insulating layer 146 can be formed of a single layer or multiple layers using an organic material such as photoacrylic or an inorganic material such as SiNx or SiOx. In addition, the interlayered insulating layer 146 can be formed of multiple layers including organic and inorganic layers, but not limited thereto.

The source electrode 115 and the drain electrode 116 can be formed of a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto. The source electrode 115 and the drain electrode 116 can be contact the source region 112b and the drain region 112c of the semiconductor layer 112 through contact holes formed in the gate insulating layer 144 and the interlayered insulating layer 146, respectively.

A bottom shield metal layer can be arranged on the substrate 140 and below the semiconductor layer 112. The bottom shield metal layer can serve to minimize back channel phenomenon caused by charges trapped in the first substrate 140 and prevent afterimages or performance degradation of transistor, and can be formed of a single layer or multiple layers using titanium (Ti), molybdenum (Mo), and/or an alloy thereof, but not limited thereto.

A first planarization layer 148 is formed over the first substrate 140 on which the thin film transistor T is formed. The first planarization layer 148 can be formed of an organic material such as photoacrylic, but not limited thereto, and can be formed of multiple layers including an inorganic layer and an organic layer.

A connection electrode 154 is formed on the first planarization layer 148 of the display region AA, and is electrically connected to the drain electrode 116 of the thin film transistor T through a contact hole formed in the first planarization layer 148.

A second planarization layer 150 is formed over the first planarization layer 148 on which the connection electrode 154 is formed. The second planarization layer 150 can be formed of an organic material such as photoacrylic, but not limited thereto, and can be formed of multiple layers including an inorganic layer and an organic layer. In addition, the second planarization layer 150 can be formed of the same material as the first planarization layer 148, but can be formed of a different material from the first planarization layer 148.

As such, in the present disclosure, by forming the planarization layers 148 and 150 of a two-layered structure, various electrodes and lines can be formed between the first and second planarization layers 148 and 150. Accordingly, since electrodes can be arranged vertically, an area of the electrodes and lines in the subpixel can be reduced, and as a result, an area of the subpixel can be reduced, making it possible to manufacture a high-resolution display apparatus 100.

Of course, depending on type, area, resolution, etc. of the display apparatus 100, a planarization layer can be configured as a single layer. In this case, the connection electrode 154 can be omitted.

A light emitting element D is disposed in the display region AA on the second planarization layer 150. The light emitting element D includes a first electrode 132, a light emitting layer 134, and a second electrode 136.

The first electrode 132 is disposed on the second planarization layer 150 and is connected to the connection electrode 154 through a contact hole formed in the second planarization layer 150, and the connection electrode 154 is connected to the drain electrode 116 of the thin film transistor T through a contact hole formed in the first planarization layer 148, so that the first electrode 132 is electrically connected to the drain electrode 116 through the connection electrode 154. The first electrode 132 can be formed of at least one of silver (Ag), aluminum (Al), gold (Au), molybdenum (Mo), tungsten (W), chromium (Cr), and an alloy thereof. In addition, the first electrode 132 can be formed of a transparent metal oxide layer, such as ITO (indium tin oxide) or IZO (indium zinc oxide).

In a case where a planarization layer is formed of a single layer and the connection electrode 154 is omitted, the first electrode 132 is disposed on the first planarization layer 148 and is directly connected to the drain electrode 116 of the thin film transistor T through a contact hole formed in the first planarization layer 148.

When the display apparatus 100 is a top emission type display apparatus, the first electrode 132 can include an opaque conductive material to function as a reflective electrode that reflects light. When the display apparatus 100 is a bottom emission type display apparatus, the first electrode 132 can be formed using a transparent conductive material that transmits light, such as ITO (indium tin oxide) or IZO (indium zinc oxide).

A bank layer BNK is formed at a boundary of each subpixel on the second planarization layer 150. The bank layer BNK can be a kind of partition wall defining the subpixel. The bank layer BNK can partition each subpixel and prevent light of specific colors output from adjacent subpixels from being mixed and output.

The bank layer BNK can be formed of at least one of an inorganic insulating material such as SiNx or SiOx, an organic insulating material such as BCB (BenzoCycloButene), an acrylic resin, an epoxy resin, a phenolic resin, a polyamide resin, or a polyimide resin, and a photosensitive material including a black pigment, but not limited thereto.

The light emitting layer 134 is formed on an upper surface (or top surface) of the first electrode 132 surrounded by the bank layer BNK. The light emitting layer 134 can be formed to extend to a side surface and a portion of an upper surface of the bank layer BNK.

The light emitting layers 134 can include an R light emitting layer that is formed in a red subpixel and emits red light, a G light emitting layer that is formed in a green subpixel and emits green light, and a B light emitting layer that is formed in a blue subpixel and emits blue light. The light emitting layer 134 can include an organic light emitting layer, or an inorganic light emitting layer, for example, a nano-sized material layer, a quantum dot light emitting layer, a micro LED light emitting layer, or a mini LED light emitting layer, but not limited thereto.

The light emitting layer 134 can include not only an organic light emitting layer, but also an electron injection layer and a hole injection layer that inject electrons and holes into the organic light emitting layer, and an electron transport layer, a hole blocking layer, an electron blocking layer, and a hole transport layer that transport the injected electrons and holes into the organic light emitting layer, but not limited thereto.

The second electrode 136 is disposed on the light emitting layer 134 and can be formed of a single layer or multiple layers using a metal and/or an alloy thereof. In addition, the second electrode 136 can be formed of a transparent metal oxide such as ITO (indium tin oxide) or IZO (indium zinc oxide), but not limited thereto.

When the display apparatus 100 is a top emission type, the second electrode 136 can be formed using a semitransparent conductive material that transmits light. For example, the second electrode 136 can be formed using at least one of alloys such as LiF/Al, CsF/Al, Mg: Ag, Ca/Ag, Ca: Ag, LiF/Mg: Ag, LiF/Ca/Ag, and LiF/Ca: Ag.

When the display apparatus 100 is a bottom emission type, the second electrode 136 can be formed using an opaque conductive material as a reflective electrode that reflects light. For example, the second electrode 136 can be formed of at least one of silver (Ag), aluminum (Al), gold (Au), molybdenum (Mo), tungsten (W), chromium (Cr), and an alloy thereof.

In addition, the light-emitting element D can be configured in a tandem structure. The tandem structure can include a plurality of light emitting layers, and a charge generation layer can be disposed between the light emitting layers. The charge generation layer is for controlling charge balance between the plurality of organic layers, and can be configured in a plurality of layers including a first charge generation layer and a second charge generation layer. The charge generation layer can include an N-type charge generation layer and a P-type charge generation layer, and can be formed of a light emitting layer doped with an alkali metal such as Li, Na, K, or Cs, or an alkaline earth metal such as Mg, Sr, Ba, or Ra, but not limited thereto.

An encapsulation layer 182 is formed on the light emitting element D to encapsulate the light emitting element D. If the light emitting element D is exposed to moisture or oxygen, a pixel shrinkage phenomenon in which a light emission region is reduced or a defect in which a dark spot is formed in a light emission region can occur. In addition, moisture or oxygen oxidizes an electrode made of metal. The encapsulation layer 182 blocks penetration of moisture and oxygen from an outside, thereby preventing the light emitting element D and various electrodes from being defective.

A dam DAM is disposed in the non-display region NA on a lower side of the display region AA and on the cut surface of the side of the display region AA. The dam DAM can be formed along the entire outer perimeter of the display panel 110 to bond the first substrate 140 and a second substrate 190 while blocking moisture from penetrating into an inside of the display panel 110. The dam DAM is formed of an organic material, but not limited thereto.

A filler 184 is disposed between the first substrate 140 and the second substrate 190 surrounded by the dam DAM. The filler 184 can be an adhesive layer that adheres the encapsulation layer 182 and the second substrate 190. At this time, the filler 184 can be formed of a thermosetting adhesive resin, a photocuring adhesive resin, or a natural curing adhesive resin.

The filler 184 can be a blocking layer for blocking penetration of moisture and oxygen into the display panel 110. In a case where the first substrate 140 and the second substrate 190 are bonded together, if a separate material is not filled into a space between the first substrate 140 and the second substrate 190, the display panel 110 can be relatively vulnerable to moisture and oxygen penetrating from the outside. Therefore, by filling the space between the first substrate 140 and the second substrate 190 with a moisture-proof layer that suppresses the penetration of moisture and oxygen, moisture and oxygen penetrating into the display panel 110 can be effectively blocked. At this time, the filler 184 can be configured to include a moisture absorbing agent or a moisture and oxygen blocking agent. For example, a getter can be included in the filler 184.

In addition, the filler 184 can be configured to include an adhesive resin that bonds the encapsulation layer 182 and the second substrate 190, and an agent that blocks moisture and oxygen.

The filler 184 can have a function of maintaining a constant gap between the first substrate 140 and the second substrate 190.

Since the filler 184 is filled inside the display panel 110 by the dam DAM, the dam DAM acts as a sealing agent that seals the filler 184.

A dam bank BDAM can be disposed inside and outside the dam DAM of the non-display region NA on a lower side of the display region AA. The dam bank BDAM can be formed of two layers. At this time, a lower layer of the dam bank BDAM can be formed of the same material as the second planarization layer 150, and an upper layer of the dam bank BDAM can be formed of the same material as the bank layer BNK, but not limited thereto.

In the drawings, the dam bank BDAM is formed on each of the inner and outer sides of the dam DAM. Alternatively, the dam bank BDAM can be formed on only one of the inner and outer sides of the dam DAM, or the dam bank BDAM can be omitted depending on a structure of the display panel 110.

The dam DAM is disposed on the first planarization layer 148. For example, the second planarization layer 150 and the light emitting layer 134 on a region of the non-display region NA are removed, and the dam DAM is formed in the removed region. As such, since the second planarization layer 150 and the light emitting layer 134 under the dam DAM are removed, moisture can be prevented from penetrating through the second planarization layer 150 and the light emitting layer 134.

The second planarization layer 150 and the light emitting layer 134 under the dam DAM can be removed in various ways. For example, the second planarization layer 150 and the light emitting layer 134 under the dam DAM can be removed in an etching process when forming the second planarization layer 150 and the light emitting layer 134.

However, in the case of manufacturing the display panels 110 of various sizes by cutting the display panels 110 as in the present disclosure, the display panels 110 of various areas are formed up to the light emitting element D through the same processes, and then the display panels 110 are cut. The formation of the dam DAM and the filler 184 and the bonding with the second substrate 190 are performed after the display panel 110 is cut.

Therefore, since the formation location of the dam DAM varies depending on the area of the cut display panel 110, the removal process of the second planarization layer 150 and the light emitting layer 134 in the region where the dam DAM is to be formed is performed after the light emitting element D is formed. In the present disclosure, the second planarization layer 150 and the light emitting layer 134 can be removed by a laser. As the second planarization layer 150 and the light emitting layer 134 are removed by a laser, the second planarization layer 150 and the light emitting layer 134 can be removed quickly and accurately at a desired position. However, the second planarization layer 150 and the light emitting layer 134 can be removed not only by the laser process, but also by other processes.

Meanwhile, the dam DAM can be disposed on the interlayered insulating layer 146. In this case, the first planarization layer 148, the second planarization layer 150 and the light emitting layer 134 of a region corresponding to the dam DAM can be removed by a laser process or the like before the formation of the dam DAM.

The pad PAD is disposed on an edge of the non-display region NA. The pad PAD is formed on the first planarization layer 148 and can be formed of the same metal as the connection electrode 154 through the same process, but not limited thereto. In addition, the pad PAD is formed on the interlayered insulating layer 146 and can be formed of the same metal as the source electrode 116 through the same process, but not limited thereto.

Connection lines 162 are disposed on the first planarization layer 148 of the non-display region NA. The connecting line 162 contacts the corresponding pad PAD and is electrically connected the pad PAD. In the drawing, the connection line 162 is formed to completely cover the pad PAD, but the connection line 162 can be formed to cover a portion of the pad PAD. In addition, an insulating layer can be formed on the pad PAD, and the connection line 162 can be disposed on the insulating layer, so that the pad PAD and the connection line 162 can be electrically connected through a contact hole formed in the insulating layer.

The connection line 162 can be formed of a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto.

The connection line 162 extends from an upper surface of the pad PAD to a lower surface (or bottom surface) of the first substrate 140 through a side surface of the first substrate 140. A protective layer 164 is formed on the connection line 162. The protective layer 164 seals the connection line 162 to prevent the connection line 162 from being corroded by external moisture, etc.

The protective layer 164 can be formed of an inorganic material or an organic material, and can be formed of a double layer including an inorganic layer and an organic layer.

The protective layer 164 is also formed on a cut surface CF of the display region AA. Since the cut surface CF is a region directly exposed to the outside, moisture can penetrate from the outside through this region. Therefore, by forming the protective layer 164 on the cut surface CF, moisture is prevented from penetrating into this region. The protective layer 164 extends from an upper surface of the second substrate 190 to the cut surface CF and the lower surface of the first substrate 140, so that the entire cut surface CF is sealed by the protective layer 164.

Meanwhile, the support substrate 120 is disposed on the lower surface of the first substrate 140, and the first substrate 140 and the support substrate 120 are bonded together by an adhesive 170.

The signal line SL is disposed on an upper surface of the support substrate 120 i.e., on one surface of the support substrate 120 facing the first substrate 140. The signal line SL is electrically connected to the printed circuit board PCB through the flexible circuit board FPC as illustrated in FIG. 1.

The signal line SL is electrically connected to the connection line 162 of the first substrate 140 through a contact hole formed in the protective layer 164, so that various signals supplied from the image processing portion, the timing control portion, the power supply portion, etc. arranged on the printed circuit board PCB are applied to various electrodes on the first substrate 140. The signal line SL can be connected to the connection line 162 through a connecting member such as a solder ball or a bump, but not limited thereto.

As described above, in the display apparatus 100 according to some embodiments of the present disclosure, since the display panels 110 are manufactured by the same process and then the display panels 110 of various sizes are manufactured by the cutting process, the manufacturing processes can be simplified and the manufacturing cost can be reduced.

In addition, in the display apparatus 100 according to some embodiments of the present disclosure, the second planarization layer 150 and the bank layer BNK of the cut region are removed and the dam DAM is formed in the removed region, so that moisture can be prevented from penetrating through the cut surface.

Furthermore, in the display apparatus 100 according to some embodiments of the present disclosure, since the protective layer 164 is formed on the side surface of the non-display region NA and the cut surface CF of the display region AA, moisture can be prevented from penetrating into the display apparatus 100 more effectively.

Furthermore, in the display apparatus 100 according to some embodiments of the present disclosure, the connection line 162 connected to the pad PAD of the non-display region NA extends to the rear side of the first substrate 140 along the side surface of the first substrate 140 and is electrically connected to the signal line SL of the support substrate 120, so that an area occupied by connection means for connecting the display panel 110 and the support substrate 120 can be minimized, thereby minimizing a scam of the tiling display apparatus 100.

Hereinafter, a method of manufacturing the display apparatus 100 according to some embodiments of the present disclosure is described in detail with reference to the attached drawings.

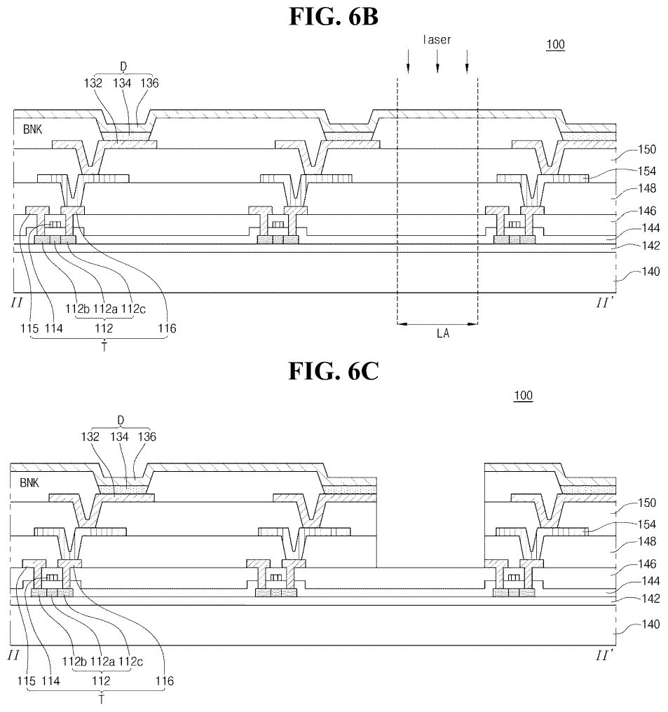

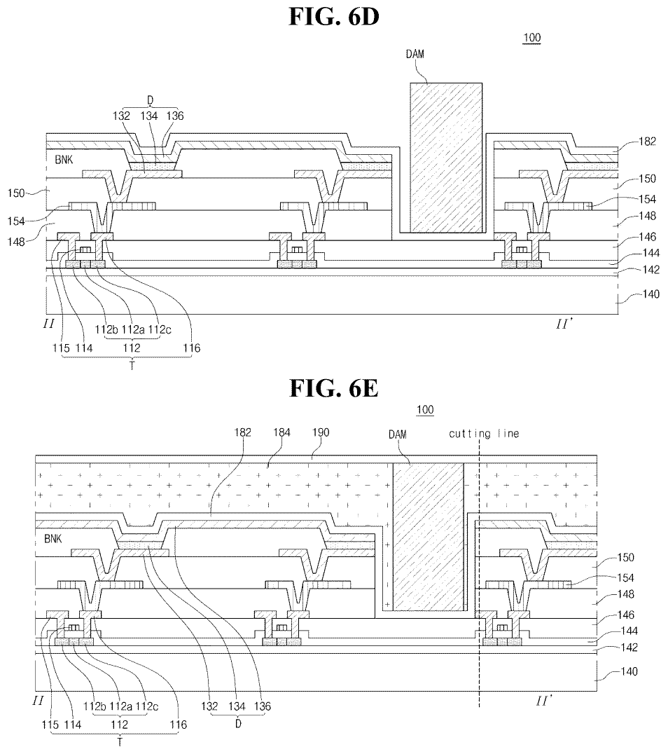

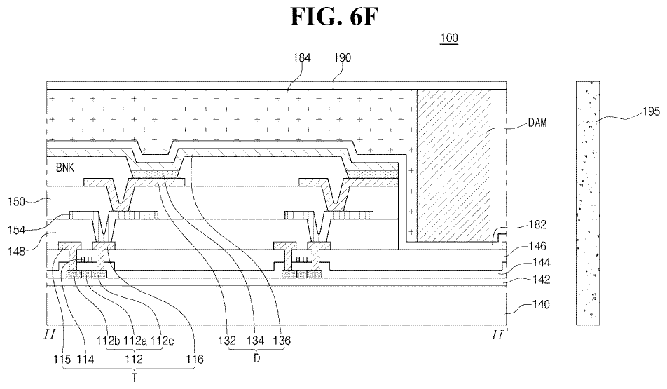

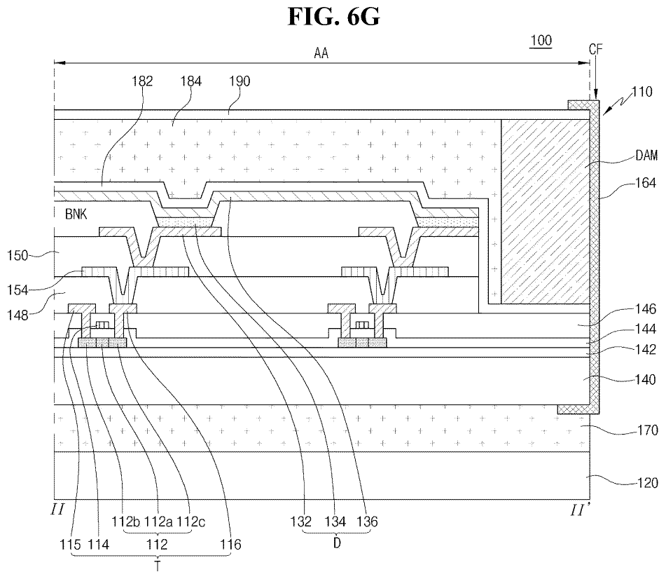

FIGS. 6A to 6G are views illustrating a method of manufacturing a display apparatus according to an embodiment of the present disclosure. Particularly, FIGS. 6A to 6G show a method of manufacturing a structure of FIG. 5B.

First, as shown in FIG. 6A, the buffer layer 142 is formed over the entire first substrate 140. The first substrate 140 can be formed of a rigid material such as glass, or a plastic material such as polyimide, polymethylmethacrylate, polyethylene terephthalate, polyethersulfone, or polycarbonate. The buffer layer 142 can be formed by laminating a single layer of SiNx or SiOx or multiple layers thereof.

Then, a polycrystalline semiconductor such as polysilicon, or an oxide semiconductor such as IGZO (Indium-gallium-zinc-oxide), IZO (Indium-zinc-oxide), IGTO (Indium-gallium-tin-oxide), or IGO (Indium-gallium-oxide) is laminated on the buffer layer 142 and etched to form the semiconductor layer 112 in each of the subpixels SP. In addition, by doping impurities on both sides of the semiconductor layer 112, the channel region 112a, the source region 112b, and the drain region 112c are formed.

Then, an inorganic material such as SiOx or SiNx is laminated to form the gate insulating layer 144. Then, a metal such as molybdenum (Mo), aluminum (Al), chromium (Cr), gold (Au), titanium (Ti), nickel (Ni), neodymium (Nd), or copper (Cu) is laminated by a sputtering method and etched by a wet etching method to form the gate electrode 114 in each subpixel SP. Then, an organic material such as photoacrylic or an inorganic material such as SiNx or SiOx is laminated on the gate electrode 114 to form the interlayered insulating layer 146, and then the interlayered insulating layer 146 on each of the source region 112b and the drain region 112c of the semiconductor layer 112 is dry etched to form a contact hole.

Next, a metal such as Cr, Mo, Ta, Cu, Ti, Al, or an Al alloy is laminated by a sputtering method and etched to form the source electrode 115 and the drain electrode 116 that are in ohmic contact with the source region 112b and the drain region 112c of the semiconductor layer 112 through the respective contact holes in each subpixel SP, thereby forming the thin film transistor T.

Then, an organic material such as photoacrylic is laminated on the source electrode 115 and the drain electrode 116 to form the first planarization layer 148, and then the first planarization layer 148 on the drain electrode 116 is dry-etched to form a contact hole.

Next, a metal such as silver (Ag), aluminum (Al), gold (Au), molybdenum (Mo), tungsten (W), chromium (Cr), or an alloy thereof is laminated on the first planarization layer 148 by a sputtering method and etched to form the connection electrode 154 on the first planarization layer 148.

Then, an organic material such as photoacrylic is laminated on the first planarization layer 148 to form the second planarization layer 150, and then the second planarization layer 150 on the connection electrode 154 is etched to form a contact hole.

Next, a metal such as silver (Ag), aluminum (Al), gold (Au), molybdenum (Mo), tungsten (W), chromium (Cr), or an alloy thereof, or a metal oxide such as ITO or IZO is laminated by sputtering and etched to form the first electrode 132 on the second planarization layer 150. At this time, the first electrode 132 is connected to the connection electrode 154 through a contact hole formed in the second planarization layer 150, and the connection electrode 154 is connected to the drain electrode 116 of the thin film transistor T through a contact hole formed in the first planarization layer 148, so that the first electrode 132 is connected to the drain electrode 116 of the thin film transistor T.

Then, at least one of an inorganic insulating material such as SiNx or SiOx, an organic insulating material such as BCB (BenzoCycloButene), an acrylic resin, an epoxy resin, a phenolic resin, a polyamide resin, or a polyimide resin, or a photosensitive material including a black pigment is laminated on the second planarization layer 150 and the first electrode 132, and etched by a dry etching method to form the bank layer BNK on the second planarization layer 150 and an edge of the first electrode 132.

Then, a light emitting material is laminated and patterned on the display area AA to form the light emitting layer 134, and then a metal or an alloy thereof, or a metal oxide is laminated and etched to form the second electrode 136 on the light emitting layer 134 and the side and upper surfaces of the bank layer BNK, thereby forming the light emitting element D.

Then, as shown in FIG. 6B, A laser is irradiated on a laser irradiation region LA inside the first substrate 140.

Accordingly, as shown in FIG. 6C, the light emitting element D, the bank layer BNK, the second planarization layer 150, and the first planarization layer 148 of the laser irradiation region LA are removed.

Then, as shown in FIG. 6D, an organic material is laminated and patterned to form the dam DAM in the laser irradiation region LA where the light emitting element D, the bank layer BNK, the second planarization layer 150, and the first planarization layer 148 are removed. Meanwhile, the dam DAM can be formed along the outer perimeter on sides of the first substrate 140 that are different from a side corresponding to the laser irradiation region LA.

Thereafter, as shown in FIG. 6E, the filler 184 is coated inside the outer perimeter of the first substrate 140, then the second substrate 190 is placed on the filter 184, and then the filler 184 is cured to attach the second substrate 190. The filler 184 can be formed of a thermosetting adhesive resin, a photocuring adhesive resin, or a natural curing adhesive resin, but not limited thereto. In addition, the filler 184 can include a moisture-proof material such as a getter.

The filler 184 can be placed between the first substrate 140 and the second substrate 190 outside the dam DAM. In this case, cutting efficiency can be reduced due to the filler 184 when cutting the display panel, the filler 184 may not be applied between the first substrate 140 and the second substrate 190 outside the dam DAM.

Then, the display panel is cut along the cutting line spaced at a certain distance from the dam DAM by a cutting wheel or laser.

Then, as shown in FIG. 6F, the cut surface is polished by a polishing device 195 to complete the display panel of the desired size.

Then, as shown in FIG. 6G, the protective layer 164 is formed on the cut surface of the display panel to seal the cut surface, and then the manufactured display panel is attached to the support substrate 120. Referring to FIG. 5A, in the non-display region NA where the pad PAD is placed, before forming the protective layer 164, the connection line 162 electrically connected to the pad PAD can be formed to extend from the upper surface of the first planarization layer 148 to the rear surface of the first substrate 140, and the protective layer 164 can be configured to seal the connection line 162.

As described above, in the display apparatus according to some embodiments of the present disclosure, since the display panels are manufactured by the same process and then the display panels of various sizes are manufactured by the cutting process, the manufacturing processes can be simplified and the manufacturing cost can be reduced.

In the display apparatus according to some embodiments of the present disclosure, the planarization layer and the bank layer of the cut region are removed and the dam is formed in the removed region, so that moisture can be prevented from penetrating through the cut surface.

In the display apparatus according to some embodiments of the present disclosure, since the protective layer is formed on the side surface of the non-display region and the cut surface of the display region, penetration of moisture into the display apparatus can be prevented more effectively.

In the display apparatus according to some embodiments of the present disclosure, the connection line connected to the pad of the non-display region extends to the rear surface along the side surface of the first substrate and is electrically connected to the signal line of the support substrate. Therefore, the area occupied by the connection means for connecting the display panel and the support substrate can be minimized, and thus the seam of the tiling display apparatus can be minimized.

In the display apparatus according to some embodiments of the present disclosure, the display panels of various sizes can be manufactured through the same process, so that production energy can be reduced due to process optimization.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display panel comprising:
a first substrate and a second substrate which include a display region and a non-display region adjacent to the display region, the display region including a plurality of subpixels;
a thin film transistor and a light emitting element arranged in each of the plurality of subpixels;
a dam arranged at the non-display region and an end of the display region between the first substrate and the second substrate; and
a protective layer disposed on a side surface of the non-display region and a side surface of the end of the display region.

2. The display panel of claim 1, wherein an organic layer below the dam is removed.

3. The display panel of claim 2, further comprising:
at least one planarization layer covering the thin film transistor; and
a bank layer disposed between the plurality of subpixels.

4. The display panel of claim 3, wherein the organic layer below the dam includes the planarization layer and the bank layer.

5. The display panel of claim 4, wherein the organic layer below the dam is removed by a laser.

6. The display panel of claim 1, further comprising:
a pad arranged on the first substrate of the non-display region;
a connection line electrically connected to the pad and extending to a lower surface of the first substrate through a side surface of the first substrate,
wherein the connection line is covered by the protective layer.

7. The display panel of claim 6, wherein the connection line completely covers the pad.

8. The display panel of claim 6, further comprising an insulating layer on the pad,
wherein the pad is electrically connected to the connection line through a first contact hole formed in the insulating layer.

9. The display panel of claim 1, wherein the end of the display region has a cut surface.

10. The display panel of claim 1, further comprising a filler placed between the first substrate and the second substrate inside the dam.

11. The display panel of claim 10, wherein the filler includes an adhesive resin.

12. The display panel of claim 11, wherein the adhesive resin contains a moisture-proof agent.

13. A display apparatus comprising:
a support substrate; and
a plurality of display panels including the display panel of claim 1, mounted on the supporting substrate.

14. The display apparatus of claim 13, wherein the plurality of display panels include display panels cut along a horizontal cutting line and/or a vertical cutting line and having different sizes.

15. The display apparatus of claim 13, further comprising a signal line disposed on an upper surface of the support substrate.

16. The display apparatus of claim 15, wherein the signal line is electrically connected to a connection line of the display panel.

17. The display apparatus of claim 13, further comprising an adhesive layer disposed between the support substrate and the display panel.
